(19) United States
(12) Patent Application Publication
(10) Pub. No.: US 2022/0384702 A1
(43) Pub. Date: Dec. 1, 2022

(54) EFFICIENT INTEGRATION OF THERMOELECTRIC DEVICES INTO HEAT EXCHANGE SURFACES FOR POWER GENERATION

(71) Applicant: AUSTIN GEOTECH SERVICES, INC., Austin, TX (US)

(72) Inventor: Mukul M. Sharma, Austin, TX (US)

(21) Appl. No.: 17/824,875

(22) Filed: May 25, 2022

Related U.S. Application Data
(60) Provisional application No. 63/193,453, filed on May 26, 2021.

(51) Int. Cl. H01L 35/30; H01L 35/32

(52) U.S. Cl. CPC H01L 35/30; H01L 35/325; F01N 5/025

(57) ABSTRACT

Systems and methods are described for generating electricity from fluid produced from a subsurface formation. The disclosed systems and methods include generating electrical power using the energy content of fluids produced from the earth or hot fluids created during surface processing of the produced fluids. Specific systems and methods describe utilizing heat and pressure of oil, gas, or water to generate electrical power.

### PRIORITY CLAIM

This patent application claims priority to U.S. Provisional Patent Application No. 63/193,453 to Sharma, filed May 26, 2021, which is incorporated by reference as if fully set forth herein.

### BACKGROUND OF THE INVENTION

### 1. Field of the Invention

Embodiments described herein relate to systems and methods for electrical power generation using the energy content of liquids and gases exposed to solid surfaces. Specific embodiments described relate to systems and methods for utilizing heat transfer that occurs on heat exchange surfaces to generate electrical power using thermoelectric devices integrated into the heat exchange surface.

### 2. Description of the Relevant Art

Heat exchange surfaces include any solid surfaces separating two fluids across which heat transfer is induced by a temperature gradient. Examples of such heat transfer surfaces include industrial heat exchangers, home furnaces and fireplace chimneys, automobile exhaust pipes, gas flares, and many others. The surfaces could be made of metals (to promote heat transfer) or insulators such as plastics or ceramics (to minimize heat transfer). The temperature difference that drives the heat from the hot to the cold side of these surfaces can be used to generate electricity using thermoelectric devices.

Industrial heat exchangers are extensively used to cool or heat fluids in chemical plants, oil, gas, and geothermal operations and other applications. In these heat exchangers fluids such as water, oil, chemicals, or gas at high temperatures are used to heat other such fluids. The transfer of heat from one fluid to another typically occurs without the fluids coming into direct contact. Instead, the heat exchange occurs by allowing the hot and cold fluids to exchange heat while separated by a material with high thermal conductivity. Typical materials that can be used to build such heat exchangers include, but are not limited to, copper, aluminum, steel, and their alloys.

There are different kinds of heat exchangers. They differ in the way they are mechanically constructed and in the flow geometry of the fluids as they exchange heat without being brought into direct contact. The most common are plate and frame heat exchangers and tube and shell heat exchangers. In a plate and frame heat exchanger, the hot and cold fluids are separated by thin plates, usually constructed of a corrosion resistant metal, that are all placed in parallel, such that the surface area of contact between the hot and cold fluids is maximized. The hot and cold channels for flow and the different sets of plates are typically separated by gaskets. A metal frame usually holds several plates together. Nuts and bolts are used to tighten the stack of plates to ensure no leakage of fluids. The hot and cold fluids enter and exit at separate locations. The flow is then distributed into the many flow channels available for them to flow into.

In tube and shell heat exchangers the hot or the cold fluid flows through a series of tubes placed in series or parallel, to increase the contact area with the other fluid that flows in a shell that surrounds the tubes and increase the residence time. In this design the area of the tubes is large and provides the area over which the heat transfer occurs. The primary advantage of this design is that the flow channels are always pipes and no transition to slot flow is needed. The heat exchanger is designed such that the hot fluid and the cold fluid have a certain residence time in the heat exchanger to allow the hot fluid to cool down to a desired temperature or the cold fluid to heat up to the desired temperature.

U.S. Pat. No. 4,734,139 to Shakun et. al. (“the '139 patent”), which is incorporated by reference as if fully set forth herein, describes a system for producing electricity from hot fluids using a heat exchanger with heat fins. The '139 patent discloses “A thermoelectric generator module which is formed with a hot side heat exchanger having extruded fins on one surface and in contact with a series of individual thermoelectric semiconductor modules on the opposite side of the exchanger. A cold side heat exchanger attached to the opposite side of the semiconductor modules from the hot side heat exchanger, producing a thermal gradient across the semiconductor modules. The semiconductor modules are placed in an arranged pattern such that a maximum of heat flow through the modules is produced.”

The '139 patent envisions the use of TEGs on flat surfaces and any curvature associated with a heat transfer surface will result in mechanical and thermal breakage and debonding of the TEGs. As stated in the '139 patent, “The geometry of each semiconductor module consists generally of a central portion having two parallel flat surfaces and providing a uniform cross section. Two channels are provided on opposite ends of the central portion for receiving wires which electrically interconnect each semiconductor module.”

Intl. Patent Pub. No. WO/2016054337A1 (“the '337 patent”), which is incorporated by reference as if fully set forth herein, teaches how to use flat plates to form a wedge shape to enhance the heat transfer and power generation. The tapered design of the inlet fluid results in an increase in the heat transfer coefficient as the fluid velocity increases and the temperature drops towards the outlet end of the tapered channel. Such devices are limited to the use of TEGs mounted on flat plates and as such cannot be used on curved heat transfer surfaces.

U.S. Pat. No. 4,292,579 to Constant (“the '579 patent”), which is incorporated by reference as if fully set forth herein, describes the use of thermoelectric devices to generate electricity from different sources of heat. The use of these devices is limited by their construction. The generator was envisioned to be a flat plate, or a series of flat plates, over which hot and cold fluids could flow and exchange heat. The TEGs and the connections between the TEGs are very susceptible to damage if applied on curved or complex heat exchange surfaces.

European patent application EP 2282357B1 (“the '357 patent”), which is incorporated by reference as if fully set forth herein, relates to and claims the benefit of priority of U.S. Provisional Patent Application No. 60/694,746 entitled Freedom Car & Vehicle Technologies Program, filed Jun. 28, 2005. The '357 patent and its priority application relate to the field of thermoelectric power generation, and more particularly to systems for improving the generation of power from thermoelectrics where the heat source varies in temperature and heat flux. The '357 patent and its priority application discuss how the power generation in such systems can be optimized by varying the voltage and current characteristics of the thermoelectric devices.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 depicts a representation of a cross section of a TEG cell apparatus, according to some embodiments.

FIG. 2 depicts a representation of an array of thermoelectric generators (TEGs), according to some embodiments.

FIG. 3 depicts a representation of an arrangement of an array of thermoelectric generation (TEG) cells in a tube and shell heat exchanger, according to some embodiments.

FIGS. 4A and 4B depict an example of a TEG array with an arrangement of heat fins that can be placed on the hot or cold side to increase the heat transfer coefficient.

FIG. 4C depicts an example of the temperature and flow of the fluids as they pass through the heat exchanger of array.

FIG. 5 depicts a representation of an embodiment for integrating thermoelectric generators in a fireplace.

FIG. 6 depicts a representation of an embodiment for integrating thermoelectric generators in the exhaust of a home heating system.

FIG. 7 depicts a representation of an embodiment for integrating thermoelectric generators in the tail pipe of an automobile.

While embodiments described in this disclosure may be susceptible to various modifications and alternative forms, specific embodiments thereof are shown by way of example in the drawings and will herein be described in detail. It should be understood, however, that the drawings and detailed description thereto are not intended to limit the embodiments to the particular form disclosed, but on the contrary, the intention is to cover all modifications, equivalents and alternatives falling within the spirit and scope of the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include”, “including”, and “includes” mean including, but not limited to.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

### DETAILED DESCRIPTION OF EMBODIMENTS

This specification includes references to “one embodiment” or “an embodiment.” The appearances of the phrases “in one embodiment” or “in an embodiment” do not necessarily refer to the same embodiment, although embodiments that include any combination of the features are generally contemplated, unless expressly disclaimed herein. Particular features, structures, or characteristics may be combined in any suitable manner consistent with this disclosure.

It is to be understood the present invention is not limited to particular devices or methods, which may, of course, vary. It is also to be understood that the terminology used herein is for the purpose of describing particular embodiments only, and is not intended to be limiting. As used in this specification and the appended claims, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

The present disclosure recognizes that heat transfer on heat exchange surfaces may be utilized to generate electrical power by integrating thermoelectric devices into heat exchange surfaces. Embodiments described in the present disclosure make reference to two types of heat exchangers— (1) plate and frame heat exchangers and (2) tube and shell heat exchangers. There are, however, many kinds of heat exchangers including additional heat exchangers that have been used in the past and some that are still being developed. The disclosed embodiments may apply to many of these different types of heat exchangers without deviating from the intended scope of the disclosed embodiments.

The surface processing of fluids in chemical plants and oil and gas facilities can lead to fluid streams that contain a great deal of heat. For example, gases are sometimes flared, and this process leads to the production of very hot flue gases. Produced gas produced from the subsurface is often compressed leading to a significant increase in temperature of the produced gas. Produced water or oil can be quite hot and contain significant amounts of heat energy. Chemicals produced and used in chemical processing and refineries may also be at high temperatures. Power generation equipment, gas compressors, and other fluid processing equipment generate a very significant amount of heat, which may, in some embodiments, be used by the methods described herein.

The term “heat exchange surface” is used in this application to broadly describe not just industrial heat exchangers but also other surfaces across which heat transfer occurs. In many instances, this heat is wasted and not utilized to produce any useful work. In some instances (as in heat exchangers), the hot fluid is deliberately cooled, through the use of large conductive heat exchange surfaces. Heat exchange surfaces can also be implemented in homes. Examples of this include fireplaces and chimneys in homes. Hot flue gases from the fireplace expose the ceramic and metal surfaces to very high temperatures while the other side of these heat exchange surfaces remain much cooler. The incorporation of thermoelectric devices in such surfaces can be an efficient way to generate electricity from the heat that would otherwise be wasted. Similarly, exhaust gases from the tail pipe of automobiles can be several hundred degrees warmer than the ambient air. The heat transfer through the tailpipe metal can be used to generate electrical power if thermoelectric devices are properly integrated into the tailpipe. These are just a few examples of heat transfer surfaces into which thermoelectric devices can be integrated in the manner described in the present disclosure.

The disclosed embodiments present systems and methods that differ from those previously disclosed (including those described above). For instance, the thermoelectric generators discussed above envisioned power generation by heat exchange across a flat surface, both on the hot and the cold side. In addition, the thermoelectric cells are placed within the heat exchangers in a manner that is mechanically rigid and fixed. This limits the use of these devices to flat and rigid hot or cold surfaces. They do not teach the use of thermoelectric devices on curved surfaces. Such use would result in bending stresses that will cause mechanical failure of the mechanically rigid thermoelectric cells. Mechanical stresses can also be induced by non-planar plates or by thermal cycling. Both these conditions are likely to be met in many applications.

To minimize bending and shear stresses acting on the TEG, an array of TEG cells needs to be used in a way that provides sufficient flexibility for the array to deform without transmitting the stresses to the TEG cells and the electrical connectors that connect them. The present disclosure teaches how to implement this by varying the size and shape of the TEG cells and by using flexible electrical connectors that allow some level of movement of the individual TEG cells. For example, smaller, slender rectangular cells or more flexible connectors can be used when the hot or cold surface is more curved.

In some embodiments, the array of TEGs and hot and cold heat exchangers can be placed in stacks that can then be tightly pushed together to form a good fluid seal and provide good thermal contact between the various elements. The hot and cold fluids can be distributed evenly in the hot and cold heat exchangers placed in parallel, thereby increasing the power generation capacity of the TEG arrays.

The modular design disclosed herein provides a simple way to increase the power generation capacity of the device. In some embodiments, the hot and cold heat exchangers are identical in design such that it is easy to expand the power generation capacity. The modular sandwich plate design allows multiple flexible sheets (either curved or flat) to be stacked together.

Embodiments disclosed herein also provide an advantage over previous methods through the use of flexible electrical connections between the TEGs to allow the array to be deployed on curved surfaces. In some embodiments, the electrical connections can be made using flexible polymer sheets with copper or other electrically conducting material deposited on the sheet in a prescribed pattern to make the electrical connections. This method allows the use of wires or solder to be avoided, thereby providing better reliability and making the devices more compact.

In past designs the use of solder joints has resulted in poor reliability. Thermal cycling of the devices can result in failure of solder joints resulting in poor performance. The present disclosure describes designs that do not rely on the use of solder joints. All (or a substantial number of) electrical connections can be made with flexible connections that are much more resistant to thermal and stress cycling. This may be particularly important for curved surfaces.

Thermally insulating gaps are needed in the space between the TEGS. In some embodiments, these gaps can be filled with thermally insulating material, such as a solid insulator, air, or vacuum.

To improve heat transfer at the fluid-solid and solid-solid interfaces, thermal interface materials must be used. These materials must be sufficiently heat tolerant and non-volatile to ensure that they remain at the interface for extended periods of time. In addition, it is important to select thermal interface materials that remain at the interface when the array is subjected to thermal and stress cycles.

To ensure that a high temperature difference is maintained across the TEG and the maximum heat flux occurs through the TEG (and not through any other portion of the heat exchanger surfaces), the thermal resistance of the gap needs to be impedance matched with the impedance of the TEG. This ensures that both the heat flux through the TEG is high and the temperature difference across it remains high. Both these factors control the amount of electricity generation capacity of the device. The disclosed embodiments ensure that these conditions are optimized.

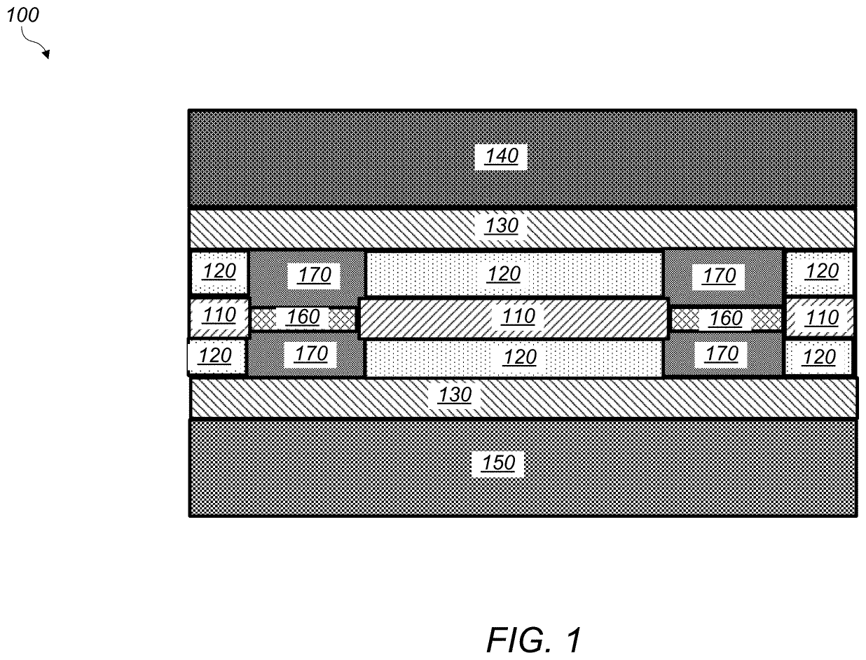

Another method that can sometimes be used to preferentially direct the heat flux through the TEG is the use of a thermal concentrator on both the hot and the cold side heat exchangers. FIG. 1 (described in detail below) illustrates this aspect of the design. By shaping the insulating space appropriately, in some embodiments, minimize any wasted heat transfer from the hot to the cold side may be minimized. This aspect of the design can be used on flat or curves heat exchange surfaces.

In some embodiments, when the hot and cold surfaces are stacked together, it is recommended that the fluid flow be arranged in a counter-current flow direction. This means that the hottest fluid sees the fluid that has already been partially warmed up in the heat exchanger. This ensures that the heat flux through the TEG array is uniform.

In some instances, it is difficult to control the flow rate or direction of the hot or cold fluids. For example, this may occur when the cold side is being cooled by the ambient air (as may be the case on a home fireplace or the tailpipe of an automobile). In such instances, the conditions on the hot or the cold side of the heat exchanger may be arranged such that the heat transferred can be easily dissipated to the ambient. This ensures that the hot and cold temperatures and the heat transfer through the TEG array remain relatively constant.

In situations where there is some level of control over the fluid flow conditions, it is advantageous to ensure that the fluid flow is turbulent. This increases the heat transfer coefficient between the fluids and the heat exchanger walls. Different ways can be used to ensure that the Reynolds numbers are high enough to ensure that this condition is met. In some embodiments, the width of the plates may be reduced, in other embodiments the number of heat exchange surfaces placed in parallel may be reduced. These will increase the fluid velocity and the heat transfer coefficient.

The present disclosure recognizes that the generation of electricity with little or no carbon emissions requires new methods for extracting energy from primary energy sources. Chemical plants, oil, gas, and geothermal facilities have fluid streams at temperatures and pressures that can be substantially elevated. In many instances these fluids need to be cooled. This cooling can be achieved through the use of industrial heat exchangers. In various embodiments, these fluids with elevated temperature and pressure may provide a source of energy that can be extracted to generate electricity (e.g., electrical power). Additionally, the source of energy or the generated electricity can be utilized and transported efficiently. The present disclosure describes carbon neutral methods to extract energy from these fluids and convert the energy to electricity by combining a modular array of thermoelectric generators with the heat exchange surface.

In certain embodiments, thermoelectric devices are implemented in plate and frame heat exchangers. FIG. 1 depicts a representation of a cross section of a TEG cell apparatus, according to some embodiments. In the illustrated embodiment, apparatus 100 includes TEG cells 110, thermally conductive mediums 120, conductive plates 130, hot side path 140, and cold side path 150. In various embodiments, TEG cells are connected by flexible electrical connectors 160, which are sandwiched between thermal insulators 170. In various embodiments, TEG cells 110 are sandwiched between hot and cold side heat exchange surfaces (e.g., plates 130) that incorporate an array of thermoelectric generators (TEGs). In some embodiments, hot side path 140 and cold side path 150 may include heat fins to promote heat exchange in the paths.

In certain embodiments, TEG cells 110 (e.g., the thermoelectric devices) are placed between two thermally conductive mediums 120. Mediums 120 protect TEG cells 110 from potentially corrosive brines, oils, or gases. Heat is efficiently transferred from the fluid to the conducting surfaces of plates 130 and then through the thermoelectric generator (TEG) elements 110. The hot fluid flows through a flow channel at a high fluid velocity in hot fluid path 140 to ensure a high heat transfer coefficient. The Reynolds number should ideally be more than 2100 such that the flow remains turbulent. The eddies in such turbulent flow help to increase the heat transfer rate from the fluid to the solid surface.

In various embodiments, an electrically connected array of TEG cells 110 is placed between the thermally conductive plates 130 that may be flat or curved to generate the power. In certain embodiments, an array of TEG cells 110 is used to ensure that the TEG cells do not break when the plates 130 are pressed together to seal the fluid flow channels with gaskets. A large, curved TEG may be very likely to bend, shear, or break when subjected to non-uniform stresses induced by a very small non-planarity in the plates and gaskets.

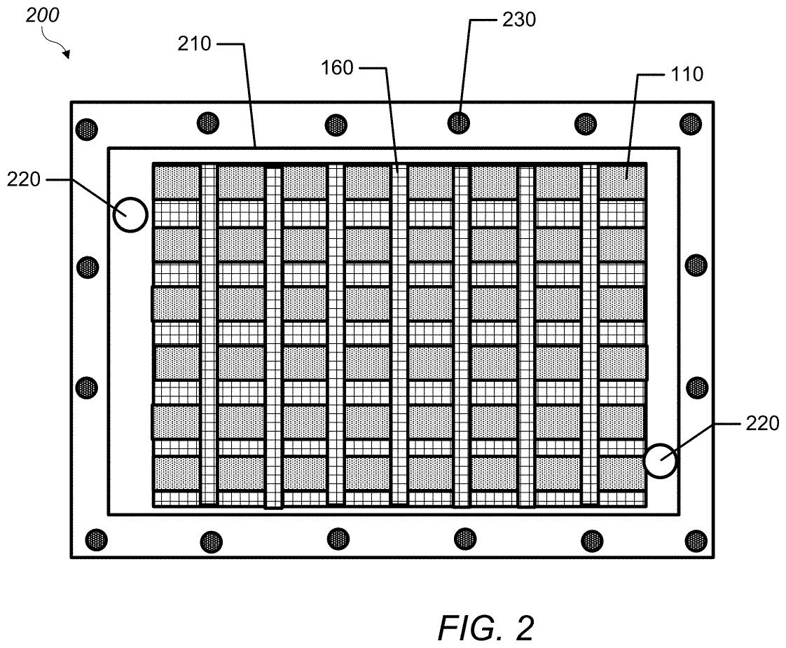

FIG. 2 depicts a representation of an array of thermoelectric generators (TEGs), according to some embodiments. In the illustrated embodiment, array 200 includes an array of TEG cells 110 connected by flexible connectors 160. A gasket or fluid seal 210 may be positioned around the TEG cells 110 and fluid inlet/outlet ports 220. Fasteners 230 may be placed around the perimeter of seal 210. In some embodiments, fasteners 230 may allow multiple sheets of TEG cells 110 and flexible connectors 160 to be placed in parallel and sealed inside the area of seal 210.

In some embodiments, array 200 includes a single heat exchange surface that incorporates an array of thermoelectric generator cells 110 (TEGs) that could be used on a curved surface such as a heat exchanger. In the TEG array 200, TEG cells 110 are connected electrically to each other by flexible electrical connectors 160 such that the power generated can be harvested from the array 200. In certain contemplated embodiments, these connections connect each row or column together. The connected structure then feeds into an electrical bus bar (not shown) that is capable of carrying a large amount of voltage or current without overheating. The size of the TEG cells 110 can be varied based on the curvature of the surface on which the array is being deployed. Smaller cells may be used when the surface is more curved.

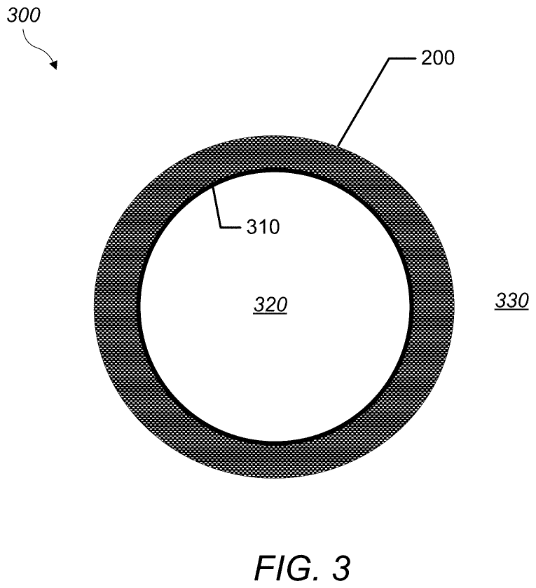

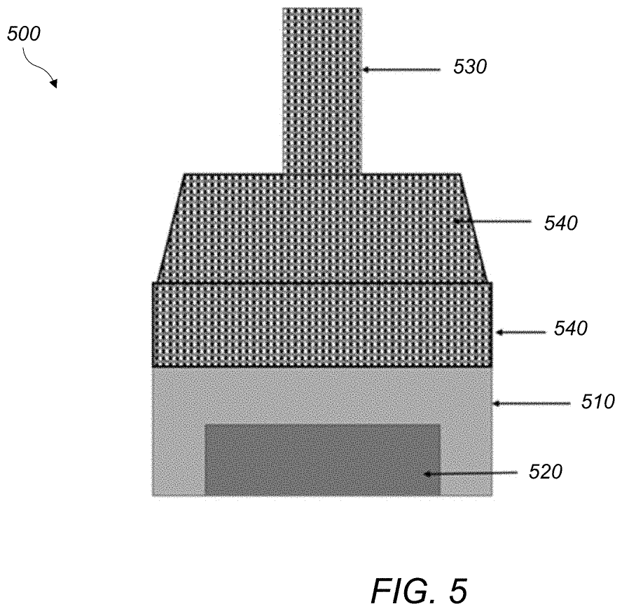

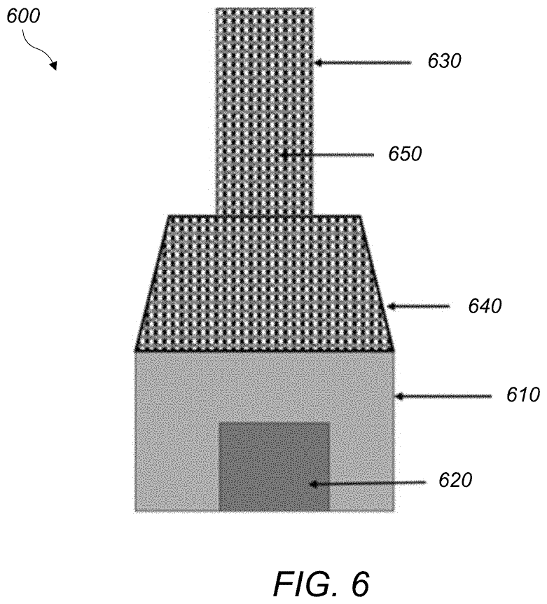

The use of many TEG cells 110 with different shapes and sizes and connected with flexible electrical connectors 160 allows the array 200 of TEG cells to be bent and molded to conform to any shape. For example, if the source of the hot fluid is a cylinder, as would be the case for an automobile tailpipe, the array can consist of small, slender rectangles that be folded around the tailpipe with their long dimension oriented along the axis of the cylinder. Other examples of hot solid surfaces that are not flat include: tube and shell heat exchangers (such as shown in FIG. 3), pipes containing hot flue gases coming off a home furnace (such as shown in FIGS. 5 and 6), a compressor exhaust, or a gas flare. In each case, the hot fluid is flowing through a pipe that typically has a circular cross section. The flexible TEG array 200 can be wrapped around the hot, solid, curved surface and used to convert the heat into electricity. In some embodiments, the heat transfer surface can be replaced by one with one that has heat fins or a material that has a higher thermal conductance. This will provide better heat transfer from the fluid to the TEG array.

On the cold side, the TEG may be left exposed to the ambient or have a constant flow of colder fluid flowing across the TEG cells (as shown in FIG. 1). One embodiment of this would be air being blown across the TEG cell array 200. In some embodiments, the TEG cells 110 may need to be protected from the ambient or electrically insulated from the ambient. In such embodiments, the cold side can be enclosed by a cold side shield (e.g., medium 120 and plate 130) to protect the TEGs from the cold side fluid. In various embodiments, the cold fluid will be continuously circulated in an open space or an enclosed channel. The cold fluid may include air flow generated by a fan or water flow driven by a pump. Other fluids and fluid flow drivers such as compressors or gravity may also be used.

Several solid hot and cold surfaces sandwiching the TEG cells can be placed in series or parallel to distribute the flow as desired. For example, if the flow rate of water or brine is 10,000 bbl/day, 10 plates may be placed in parallel to direct about 1000 bbl/day through each hot or cold flow channel. In addition, the gap between the plates and the width of the channels can be adjusted to achieve the high desired Reynolds number. The high Reynolds number may result in a high heat transfer coefficient.

The flow rate of the fluids through the channels may be important because the flow rate can directly impact the Nusselt number or the heat transfer coefficient. Fluids flowing in laminar flow are expected to have a heat transfer coefficient that is less than one half that achieved by fluids in turbulent flow. The volumetric flow rate of the fluid and the width of the slot through which the fluids are flowing can be adjusted to ensure that the flow remains turbulent. In addition, the thermal conductance of the sheets and the TEG can be adjusted to ensure that the heat flux through the TEG is maximized and the temperature across the TEG is as large as possible. This is achieved by selecting different thicknesses and materials for the plates. Adjusting these parameters ensures that the maximum heat to electrical power conversion efficiency is achieved.

In certain embodiments, excellent thermal contact is maintained between the plates and the TEG cells. This can be achieved with different thermal contact interface materials such as thermal greases, pastes, compressible sheets, etc. These materials may be used as mediums 120, shown in FIG. 1.

FIG. 3 depicts a representation of an arrangement of an array of thermoelectric generation (TEG) cells in a tube and shell heat exchanger, according to some embodiments. Apparatus 300 is an example of the use of the disclosed flexible TEG array 200 to recover heat by installing the array in a tube and shell heat exchanger. In the illustrated embodiment, apparatus 300 includes tube 310 with fluid flow 320 inside the tube and fluid flow 330 outside the tube.

In certain embodiments, the TEG array 200 with its hot and cold side plates are bent to conform to the shape of the tube 310 in the heat exchanger. In some embodiments, the TEG array 200 could be thermally attached directly to the outside of the tube 310 in the heat exchanger. The cold side of the TEGs could be left exposed to the cold side fluid (e.g., fluid 330) or protected by covering up the TEG array with a protective covering. Heat fins and other modifications discussed earlier could also be used in this application.

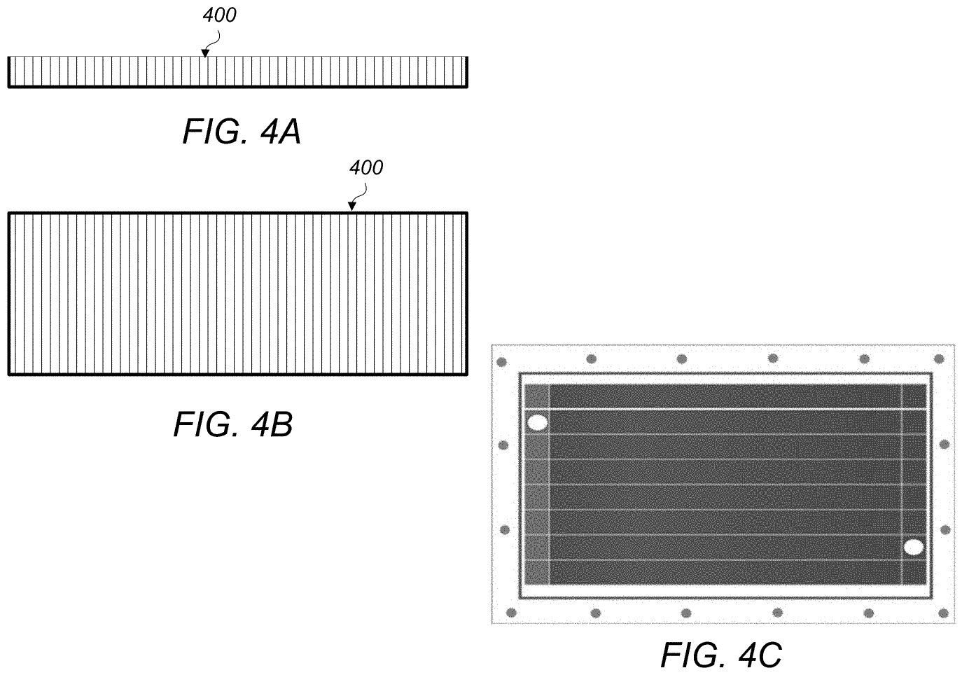

In some embodiments, heat fins may be used to increase the contact area between the fluid and the thermally conducting sheets. FIGS. 4A and 4B depict side and top view representations, respectively, of an embodiment of fins 400. Fins 400 may be placed on one or both surfaces of TEG array 200. FIG. 4C depicts an example of the temperature and flow of the fluids as they pass through the heat exchanger of array 200. In FIG. 4C, the hot fluid (red) enters on the right and the cold fluid (blue) exits on the left. In various embodiments, the flow is determined by the geometry of the fins. For instance, the fins can be constructed in different ways with different materials having high thermal conductivity. The fins can increase the time over which the fluid is in contact with the plates. The fins can also be used to change the flow orientation of the fluid relative to the plates. In some embodiments, the flow can be parallel to the plates while, in other embodiments, the flow can be at some angle to the plates. In each of these embodiments, the heat flux from the hot to the cold plate is increased and the temperature difference across the TEG is increased.

In various embodiments, the shape of the heat transfer surfaces used to confine the TEGs can be varied. For instance, the shape may be varied to increase the surface area of contact between the plates and the fluid. Undulations in the surface may allow better contact with the TEG and also allow a larger gap between hot and cold fluid in the gaps between the TEGs. This can reduce the wasted “parasitic” heat losses due to conduction in regions of the plate not in direct contact with the TEG. Other shapes of plates such as corrugated plates or plates with small-scale or large-scale surface undulations can be envisioned that achieve a similar effect. Undulations or other features on the surfaces can also serve to promote turbulence in the flow resulting in higher heat transfer from the fluid to the solid. Materials with a microstructure that leads to a larger specific surface area can also be used to increase the fluid-solid surface area.

In some embodiments, a way of increasing the heat transfer rate on both the hot and cold side heat exchangers is to direct the fluid flow in a particular manner relative to the surfaces that are in contact with the TEG array. This direction of fluid flow may be achieved by using heat fins that direct the flow. In one embodiment, the heat fins are oriented in a manner that forces the fluid to impinge as a slot jet onto the plates in contact with the TEG array. It is well known that the heat transfer coefficient for a fluid that impinges on the surface is much higher than the heat transfer coefficient for the same fluid flowing parallel to the surface. Thus, this geometry of the heat fins may increase the heat transfer rate by a factor of two or more. Other flow geometries can be envisioned where the fluid jet hits the surfaces in contact with the TEG array at an angle.

Thermoelectric generators may be built for use with fluids at many different temperatures. In some embodiments, the hot fluids may be in the temperature range of 50° C. to 200° C. In other embodiments, the fluid may be at much higher temperatures ranging from 400° C. to over 1000° C. Regardless of the temperature of the fluids, the disclosed embodiments may be applied. In certain embodiments, the materials that work best over a given temperature range are used to construct the TEG. In some embodiments, the materials with the highest efficiency at a reasonable cost may be chosen. As is known, there are different methods to construct TEGs. Thin film TEGs may be contemplated for certain embodiments herein but other more traditional TEG construction methods may also be used to construct the TEGs.

The TEG array disclosed herein can be used to extract energy from a variety of hot fluids. For example, the TEG arrays can be used in homes to recover heat from home heating systems or from fireplaces. An example of such a hot fluid is the flue gas that is vented from a chimney in a home or an industrial facility. As currently deployed, most of the heat from home furnaces and fireplaces that burn natural gas, coal, firewood, fuel oil, or other combustible energy sources, is wasted as it escapes up the chimney with the flue gas. The use of TEG arrays in conjunction with these devices provides a simple way of capturing some of this heat and utilizing it in the home or providing it back to the grid.

FIGS. 5 and 6 depict examples of heat capture from exhaust gas, according to some embodiments. FIG. 5 depicts a representation of an embodiment for integrating thermoelectric generators in a fireplace (such as those used in homes and commercial buildings). In the illustrated embodiment, fireplace 500 has housing 510 (typically ceramic tiles) and fire pit 520 attached to chimney 530. In certain embodiments, an array of TEG cells 540 are positioned around portions of housing 510 and chimney 530, as shown in FIG. 5. In various embodiments, TEG cells 540 are attached to or embedded in housing 510 and chimney 530 though other coupling methods may be contemplated. Other embodiments with less or more TEG cells positioned around housing 510 and/or chimney 530. With a flame burning in fire pit 520, TEG cells 540 are exposed to hot exhaust from the fire pit along the walls of housing 510 and chimney 530.

FIG. 6 depicts a representation of an embodiment for integrating thermoelectric generators in the exhaust of a home heating system. In the illustrated embodiment, heating system 600 includes furnace housing 610 and heat source 620 (e.g., a furnace for burning fuel to generate heat) attached to chimney 630. System 600 also includes heat exchanger 640 for heating a flow of air to heat the home. In certain embodiments, an array of TEG cells 650 are positioned around portions of chimney 630 and heat exchanger 640, as shown in FIG. 6. In various embodiments, TEG cells 650 are attached to or embedded in chimney 630 and heat exchanger 640 though other coupling methods may be contemplated. Other embodiments with less or more TEG cells positioned around chimney 630 and/or heat exchanger 640. With heat source 620 generating heat, TEG cells 650 are exposed to hot exhaust from the heat source along the walls of chimney 630 and heat exchanger 640.

In the embodiments of FIGS. 5 and 6, the TEGs are exposed to the exhaust fumes or the hot flue gases on one side while the other side is exposed to the ambient air. The exhaust fumes and flue gases from furnaces and fireplaces can have temperatures in excess of 500° F. (260° C.), so the conversion of this heat to electricity can be quite efficient. One of the keys to accomplishing this conversion is to use TEG arrays that are flexible and can be wrapped around or integrated into curved, hot surfaces. The TEG array sandwiched between two thermally conductive surfaces can be mounted near the base of the chimney where the flue gas temperature is the highest or at any location along the chimney where it is convenient. The temperature of the flue gas being vented can be high (about 600° C.) and the heat content of the gas is large. The TEG array can be mounted as a flat plate or conform to the curvature of the chimney stack. The air around the chimney provides the cool side fluid. The cool side can be covered by a conductive plate or left exposed to the ambient air. Covering the cool side of the TEG array with a plate provides better electrical isolation of the connectors between TEGs. In some embodiments, it may be necessary to install a heat tube or a fan to continuously cool the cold side plate.

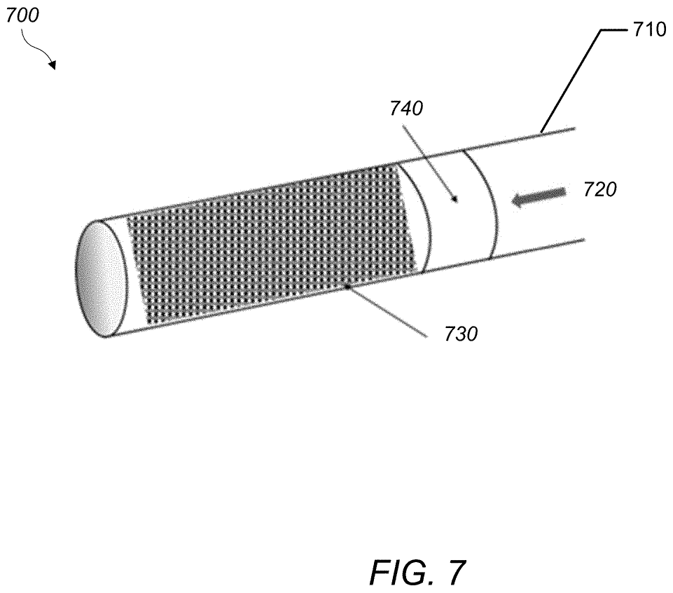

Another example of the application of flexible TEG arrays for power generation is heat recovery from the tailpipe of automobiles. FIG. 7 depicts a representation of an embodiment for integrating thermoelectric generators in the exhaust of an automobile. In the illustrated embodiment, system 700 includes exhaust pipe 710 (e.g., tailpipe) with hot exhaust gases 720 flowing through the pipe and array of TEG cells 730 coupled around the pipe. Additionally, inverter 740 may be positioned on pipe 710.

The exhaust from the pipe 710 of automobiles and trucks can vary in temperature based on the type of engine and the operating conditions. The TEG array 730 can be wrapped around all or be made a part of the tailpipe with the ambient air acting as the cold side fluid. The TEG array 730 never comes into contact with the exhaust gases 720 and also does not interfere with the flow of the exhaust gases. The heat flux through the TEG array 730 can generate electrical power than can be stored in the automobile battery or used directly in the operation of the automobile. In certain embodiments, inverter 740 is included to convert the energy to a safe voltage or convert the voltage from DC to AC.

Further modifications and alternative embodiments of various aspects of the embodiments described in this disclosure will be apparent to those skilled in the art in view of this description. Accordingly, this description is to be construed as illustrative only and is for the purpose of teaching those skilled in the art the general manner of carrying out the embodiments. It is to be understood that the forms of the embodiments shown and described herein are to be taken as the presently preferred embodiments. Elements and materials may be substituted for those illustrated and described herein, parts and processes may be reversed, and certain features of the embodiments may be utilized independently, all as would be apparent to one skilled in the art after having the benefit of this description. Changes may be made in the elements described herein without departing from the spirit and scope of the following claims.

What is claimed is:

1. A device for generating electricity, comprising:
a plurality of thermoelectric generator (TEG) cells arranged in an array;
a first thermally conductive surface placed on a first side of the array;
a second thermally conductive surface placed on a second side of the array;
a flexible electrical connector coupling at least two of the TEG cells in the array;
a thermal interface material surrounding at least a portion of the plurality of TEG cells, wherein the interface material is positioned between the array and the first thermally conductive surface and between the array and the second thermally conductive surface; and
a thermally insulating material at least partially surrounding the flexible electrical connector, wherein the insulating material is positioned in a gap between the TEG cells.

2. The device of claim 1, further comprising a plurality of flexible electrical connectors with each TEG cell coupled to at least one other TEG cell by at least one flexible electrical connector.

3. The device of claim 1, further comprising a bus bar electrically coupled to the plurality of TEG cells.

4. The device of claim 1, wherein the interface material is a thermally conductive medium.

5. The device of claim 1, wherein the insulating material is thermally insulating and electrically insulating.

6. The device of claim 1, wherein the array of TEG cells has at least some flexibility.

7. The device of claim 1, wherein a size and shape of the TEG cells allows the TEG cells to conform to a curvature of a curved surface.

8. The device of claim 1, wherein the device is capable of being conformed to a curved surface.

9. The device of claim 1, wherein the first side of the array is a hot side of the array and the second side of the array is a cold side of the array.

10. The device of claim 1, wherein at least one of the first thermally conductive surface and the second thermally conductive surface includes heat fins.

11. The device of claim 1, wherein the flexible electrical connector includes an electrically conductive metal and a flexible electrically insulating material.

12. The device of claim 1, wherein the insulating material is positioned in between the TEG cells and in between the interface material surrounding the TEG cells.

13. The device of claim 12, wherein the insulating material creates a gap between neighboring TEG cells, and wherein the gap has a thermal impedance that matches a thermal impedance of a TEG cell.

14. A method for generating electricity, comprising:
flowing a hot fluid on a first side of an array of thermoelectric generator (TEG) cells, wherein the array includes a plurality of flexible electrical connectors with each TEG cell coupled to at least one other TEG cell by at least one flexible electrical connector, and wherein the first side of the array includes a first thermally conductive surface in contact with the hot fluid, a thermal interface material positioned between the first thermally conductive surface and the array of TEG cells, and a thermally insulating material between the first thermally conductive surface and the plurality of flexible electrical connectors;
flowing a cold fluid on a second side of the array of TEG cells, wherein the second side of the array includes a second thermally conductive surface in contact with the cold fluid, the thermal interface material positioned between the second thermally conductive surface and the plurality of TEG cells, and the thermally insulating material between the second thermally conductive surface and the plurality of flexible electrical connectors; and
generating at least some electricity with the array of TEG cells.

15. The method of claim 14, further comprising bending the array of TEG cells with at least some curvature.

16. The method of claim 14, wherein the cold fluid is ambient air.

17. The method of claim 14, wherein the flow of hot fluid includes turbulent flow.

18. The method of claim 14, wherein the array of TEG cells includes a stack of TEG cells, flexible electrical connectors, first and second thermally conductive surfaces, interface material, and insulating material.

19. The method of claim 18, further comprising flowing the hot fluid and the cold fluid in a first layer of the stack in a counter-current direction from the hot fluid and the cold fluid in a second layer of the stack.

20. The method of claim 14, further comprising positioning the array of TEG cells on a surface selected from the following surfaces: an automobile exhaust pipe surface, a fireplace exhaust surface, a flue gas exhaust surface, a tube and shell heat exchanger surface, a plate and frame heat exchanger surface.
